(19) United States
(12) Patent Application Publication
(10) Pub. No.: US 2022/0376158 A1
(43) Pub. Date: Nov. 24, 2022

(54) THERMOELECTRIC DEVICE

(71) Applicant: LG INNOTECK CO., LTD., Seoul (KR)

(72) Inventors: Myoung Lae ROH, Seoul (KR); Yong Sang CHO, Seoul (KR); Hyung Eui LEE, Seoul (KR)

(21) Appl. No.: 17/775,355

(22) PCT Filed: Nov. 19, 2020
(86) PCT No.: PCT/KR2020/016371

§ 371 Date: May 9, 2022

(30) Foreign Application Priority Data
Nov. 22, 2019 (KR) 10-2019-0151316

(51) Int. Cl. H01L 35/32; H01L 35/04

(52) U.S. Cl. CPC H01L 35/32; H01L 35/04

(57) ABSTRACT

A thermoelectric element according to one embodiment of the present disclosure includes a first substrate, a first resin layer disposed on the first substrate, a first electrode disposed on the first resin layer, a P-type thermoelectric leg and an N-type thermoelectric leg disposed on the first electrode, a second electrode disposed on the P-type thermoelectric leg and the N-type thermoelectric leg, a second resin layer disposed on the second electrode, and a second substrate disposed on the second resin layer, wherein at least one of the first electrode and the second electrode includes a copper layer, first plated layers disposed on both surfaces of the copper layer, and second plated layers disposed between both surfaces of the copper layer and the first plated layers, materials of the first plated layer and the second plated layer are different from each other, and the first plated layer has a melting point greater than or equal to 300° C., and an electrical conductivity greater than or equal to 9×10⁶ S/m.

### TECHNICAL FIELD

The present disclosure relates to a thermoelectric element, and more specifically, to an electrode of the thermoelectric element.

### BACKGROUND ART

A thermoelectric phenomenon is a phenomenon which occurs by movement of electrons and holes in a raw material, and refers to direct energy conversion between heat and electricity.

A thermoelectric element is a generic term for an element using the thermoelectric phenomenon, and has a structure in which a P-type thermoelectric raw material and an N-type thermoelectric raw material are joined between metal electrodes to form a PN junction pair.

Thermoelectric elements can be classified into an element using temperature changes of electrical resistance, an element using the Seebeck effect, which is a phenomenon in which an electromotive force is generated due to a temperature difference, an element using the Peltier effect, which is a phenomenon in which heat absorption or heat generation by current occurs, and the like.

The thermoelectric element is variously applied to home appliances, electronic components, communication components, or the like. For example, the thermoelectric element can be applied to a cooling device, a heating device, a power generation device, or the like. Accordingly, the demand for thermoelectric performance of the thermoelectric element increases more and more.

The thermoelectric element includes substrates, electrodes, and thermoelectric legs, a plurality of thermoelectric legs are disposed between an upper substrate and a lower substrate, a plurality of upper electrodes are disposed between the plurality of thermoelectric legs and the upper substrate, and a plurality of lower electrodes are disposed between the plurality of thermoelectric legs and the lower substrate. In this case, the upper substrate and the plurality of upper electrodes and the lower substrate and the plurality of lower electrodes can be respectively bonded by resin layers.

Generally, the electrode applied to the thermoelectric element can include a copper (Cu) layer and a nickel (Ni) layer plated on both surfaces of the copper layer. The nickel layer can prevent diffusion of copper of the copper layer toward the resin layers or the thermoelectric legs. Meanwhile, there is a problem in that the nickel layer has a smooth surface, and has poor wettability with a solder used for bonding between the electrode and the thermoelectric leg. Accordingly, there is an attempt to increase the bonding strength between the electrode and the thermoelectric leg by plating a surface of the nickel layer with tin (Sn) or the like.

However, the tin (Sn) has a melting point of 231.9° C., a commonly used Sn—Ag—Cu (SAC) solder has a melting point of approximately 220° C., and an SnSb solder has a melting point of approximately 232° C. The SAC solder can be reflow-treated for 5 minutes under a condition of a reflow peak of 250° C., and the SnSb solder can be reflow-treated for 5 minutes under a condition of a reflow peak of 270° C. Accordingly, during a reflow process for bonding the thermoelectric legs to the electrodes, a part of the tin (Sn) plated on the electrodes can melt. As shown in FIG. 1, since the molten tin (Sn) is aggregated in some regions, voids can be formed in a bonding surface between the electrode and the resin layer. Due to the voids formed in the bonding surface between the electrode and the resin layer, heat transfer efficiency between the substrate and the electrode decreases, and accordingly, the performance of the thermoelectric element can be degraded.

### DISCLOSURE

### Technical Problem

The present disclosure is directed to providing an electrode structure of a thermoelectric element having excellent thermal conductivity performance and bonding performance.

### Technical Solution

A thermoelectric element according to one embodiment of the present disclosure includes a first substrate, a first resin layer disposed on the first substrate, a first electrode disposed on the first resin layer, a P-type thermoelectric leg and an N-type thermoelectric leg disposed on the first electrode, a second electrode disposed on the P-type thermoelectric leg and the N-type thermoelectric leg, a second resin layer disposed on the second electrode, and a second substrate disposed on the second resin layer, wherein at least one of the first electrode and the second electrode includes a copper layer, first plated layers disposed on both surfaces of the copper layer, and second plated layers disposed between both surfaces of the copper layer and the first plated layers, materials of the first plated layer and the second plated layer are different from each other, and each of the first plated layers has a melting point greater than or equal to 300° C., and an electrical conductivity greater than or equal to 9×106 S/m.

At least one of the first resin layer and the second resin layer may be bonded to the first plated layer.

The first substrate may be an aluminum substrate, the second substrate may be a copper substrate, and an aluminum oxide layer may be further disposed between the aluminum substrate and the first resin layer.

The aluminum oxide layer may be further disposed on a surface, among both surfaces of the aluminum substrate, opposite a surface on which the first resin layer is disposed.

The thermoelectric element may further include a heat sink disposed on the copper substrate.

Each of the P-type thermoelectric leg and the N-type thermoelectric leg may include a thermoelectric material layer including BiTe, and bonding layers disposed on both surfaces of the thermoelectric material layer, and the bonding layers may be bonded to the first plated layer by a solder.

The bonding layer and the solder may include tin (Sn).

The thermoelectric element may further include a diffusion prevention layer disposed between the thermoelectric material layer and the bonding layers, wherein the diffusion prevention layer may include nickel (Ni).

The first plated layer may include silver (Ag), and the second plated layer may include nickel (Ni).

A thickness of the first plated layer may be 0.1 μm to 10 μm.

A thermoelectric element according to another embodiment of the present disclosure includes a first substrate, a first resin layer disposed on the first substrate, a first electrode disposed on the first resin layer, a P-type thermoelectric leg and an N-type thermoelectric leg disposed on the first electrode, a second electrode disposed on the P-type thermoelectric leg and the N-type thermoelectric leg, a second resin layer disposed on the second electrode, and a second substrate disposed on the second resin layer, wherein at least one of the first electrode and the second electrode includes a copper (Cu) layer, and plated layers disposed on both surfaces of the copper layer, the plated layers include silver (Ag), and the plated layers may be bonded to at least one of the first resin layer and the second resin layer.

Each of the P-type thermoelectric leg and the N-type thermoelectric leg may include a thermoelectric material layer including BiTe, and bonding layers disposed on both surfaces of the thermoelectric material layer, and the bonding layers may bonded by the plated layer and a solder.

The bonding layers and the solder may include tin (Sn).

### Advantageous Effects

According to an embodiment of the present disclosure, a thermoelectric element of which thermal conductivity performance and bonding performance are excellent, and reliability is high can be obtained. Further, according to the embodiment of the present disclosure, a thermoelectric element of which withstand voltage performance and bonding performance with a heat sink in addition to the thermal conductivity performance and the bonding performance are improved can be obtained.

In addition, according to the embodiment of the present disclosure, a thermoelectric element capable of completely satisfying all required performance differences between a low-temperature part and a high-temperature part can be obtained.

Specifically, when the thermoelectric element according to the embodiment of the present disclosure is applied to an application for power generation, high power generation performance can be obtained.

The thermoelectric element according to the embodiment of the present disclosure can be applied to not only small-sized applications but also large-sized applications such as a vehicle, a ship, a steel mill, and an incinerator, and the like.

### DESCRIPTION OF DRAWINGS

FIG. 1 is a photograph in which surfaces of electrodes are imaged after a reflow process;

FIG. 2 is a cross-sectional view of a thermoelectric element;

FIG. 3 is a perspective view of the thermoelectric element;

FIG. 4 is a perspective view of the thermoelectric element including a sealing member;

FIG. 5 is an exploded perspective view of the thermoelectric element including the sealing member;

FIG. 6 is a cross-sectional view of a thermoelectric element according to one embodiment of the present disclosure;

FIG. 7A is a cross-sectional view of a thermoelectric leg included in the thermoelectric element according to one embodiment of the present disclosure;

FIG. 7B is a cross-sectional view of an electrode included in the thermoelectric element according to one embodiment of the present disclosure;

FIG. 8 is a cross-sectional view of a thermoelectric element according to another embodiment of the present disclosure;

FIG. 9 is a cross-sectional view of a thermoelectric element according to still another embodiment of the present disclosure; and

FIG. 10 exemplifies a bonding structure between a second substrate and a heat sink.

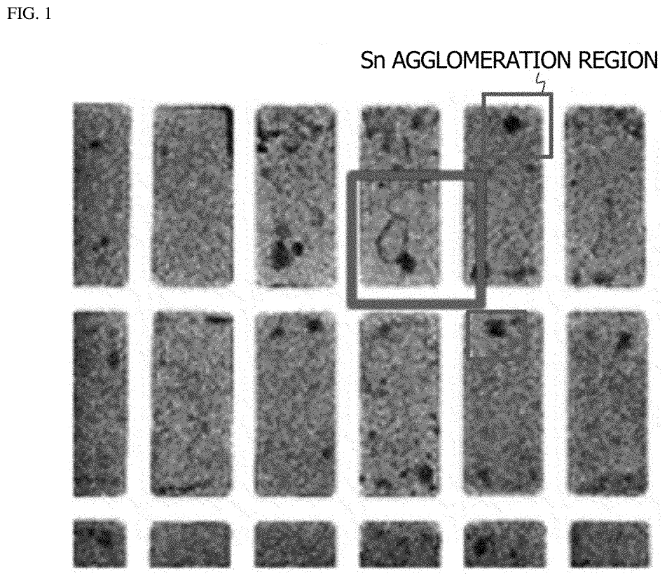

### MODES OF THE INVENTION

Hereinafter, preferable embodiments of the present disclosure will be described in detail with reference to the accompanying drawings.

However, the technical spirit of the present disclosure is not limited to some embodiments which will be described and may be embodied in various forms, and one or more elements in the embodiments may be selectively combined and replaced and used within the scope of the technical spirit of the present disclosure.

Further, terms used in the embodiments of the present disclosure (including technical and scientific terms), may be interpreted with meanings that are generally understood by those skilled in the art unless particularly defined and described, and terms which are generally used, such as terms defined in a dictionary, may be understood in consideration of their contextual meanings in the related art.

In addition, terms used in the description are provided not to limit the present disclosure but to describe the embodiments.

In the specification, the singular form may also include the plural form unless the context clearly indicates otherwise and may include one or more of all possible combinations of A, B, and C when disclosed as at least one (or one or more) of “A, B, and C”.

In addition, terms such as first, second, A, B, (a), (b), and the like may be used to describe elements of the embodiments of the present disclosure.

The terms are only provided to distinguish one element from another element, and the essence, sequence, order, or the like of the elements are not limited by the terms.

Further, when a particular element is disclosed as being “connected,” “coupled,” or “linked” to another element, the elements may include not only a case of being directly connected, coupled, or linked to another element but also a case of being connected, coupled, or linked to the other element by another element between the element and other element.

In addition, when one element is disclosed as being formed “on or under” another element, the term “on or under” includes both a case in which the two elements are in direct contact with each other and a case in which at least another element is disposed between the two elements (indirectly). Further, when the term “on or under” is expressed, a meaning of not only an upward direction but also a downward direction may be included with respect to one element.

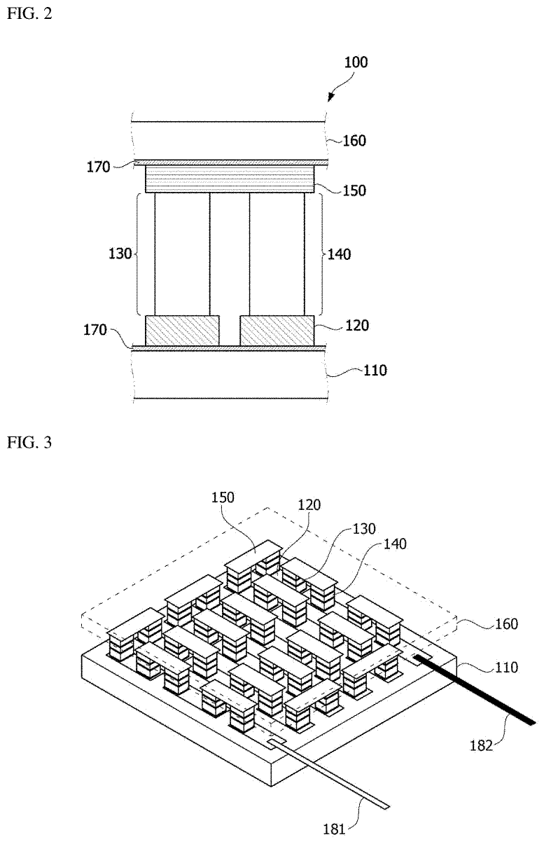

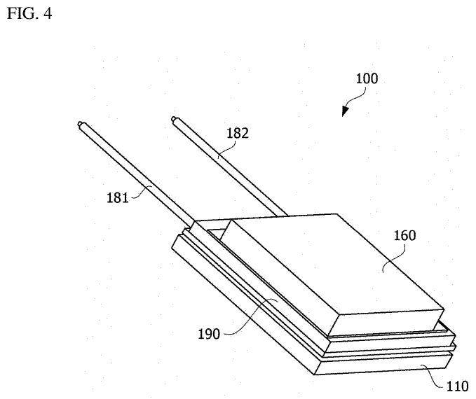

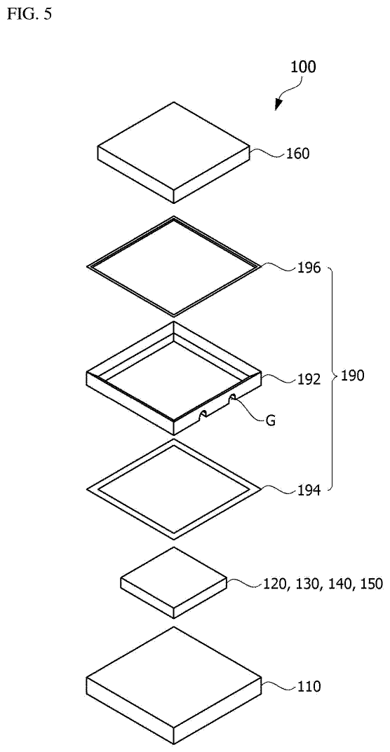

FIG. 2 is a cross-sectional view of a thermoelectric element, FIG. 3 is a perspective view of the thermoelectric element, FIG. 4 is a perspective view of the thermoelectric element including a sealing member, and FIG. 5 is an exploded perspective view of the thermoelectric element including the sealing member.

Referring to FIGS. 2 and 3, a thermoelectric element 100 includes a lower substrate 110, lower electrodes 120, a P-type thermoelectric leg 130, an N-type thermoelectric leg 140, an upper electrode 150, and an upper substrate 160.

The lower electrodes 120 are disposed between the lower substrate 110 and lower surfaces of the P-type thermoelectric leg 130 and the N-type thermoelectric leg 140, and the upper electrode 150 is disposed between the upper substrate 160 and upper surfaces of the P-type thermoelectric leg 130 and the N-type thermoelectric leg 140. Accordingly, a plurality of P-type thermoelectric legs 130 and a plurality of N-type thermoelectric legs 140 are electrically connected by the lower electrodes 120 and the upper electrode 150. One pair of the P-type thermoelectric leg 130 and the N-type thermoelectric leg 140 disposed between the lower electrodes 120 and the upper electrode 150, and electrically connected to each other may form a unit cell.

For example, when a voltage is applied to the lower electrodes 120 and the upper electrode 150 through lead lines 181 and 182, a substrate through which current flows from the P-type thermoelectric legs 130 to the N-type thermoelectric legs 140 due to the Peltier effect may absorb heat to function as a cooling part, and a substrate through which current flows from the N-type thermoelectric legs 140 to the P-type thermoelectric legs 130 may be heated to function as a heating part. Alternatively, when a temperature difference between the lower electrode 120 and the upper electrode 150 is applied, charges in the P-type thermoelectric legs 130 and the N-type thermoelectric legs 140 move due to the Seebeck effect, and thus electricity may be generated.

Here, the P-type thermoelectric leg 130 and the N-type thermoelectric leg 140 may be bismuth-telluride (Bi—Te)-based thermoelectric legs including bismuth (Bi) and tellurium (Te) as main raw materials. The P-type thermoelectric leg 130 may be a bismuth-telluride (Bi—Te)-based thermoelectric leg including at least one of antimony (Sb), nickel (Ni), aluminum (Al), copper (Cu), silver (Ag), lead (Pb), boron (B), gallium (Ga), tellurium (Te), bismuth (Bi), and indium (In). For example, the P-type thermoelectric leg 130 may include Bi—Sb—Te, which is a main raw material, in an amount of 99 to 99.999 wt %, and at least one among nickel (Ni), aluminum (Al), copper (Cu), silver (Ag), lead (Pb), boron (B), gallium (Ga), and indium (In) in an amount of 0.001 to 1 wt % based on the total weight of 100 wt %. The N-type thermoelectric leg 140 may be a bismuth-telluride (Bi-Te)-based thermoelectric leg including at least one of selenium (Se), nickel (Ni), aluminum (Al), copper (Cu), silver (Ag), lead (Pb), boron (B), gallium (Ga), tellurium (Te), bismuth (Bi), and indium (In). For example, the N-type thermoelectric leg 140 may include Bi—Se—Te, which is a main raw material, in an amount of 99 to 99.999 wt %, and at least one among nickel (Ni), aluminum (Al), copper (Cu), silver (Ag), lead (Pb), boron (B), gallium (Ga), and indium (In) in an amount of 0.001 to 1 wt % based on the total weight of 100 wt %.

Accordingly, in the specification, the thermoelectric leg may also be referred to as a semiconductor structure, a semiconductor device, a semiconductor raw material layer, a semiconductor substance layer, a semiconductor material layer, a conductive semiconductor structure, a thermoelectric structure, a thermoelectric raw material layer, a thermoelectric substance layer, a thermoelectric material layer, or the like.

The P-type thermoelectric legs 130 and the N-type thermoelectric leg 140 may be formed in a bulk type or a stacked type. Generally, the bulk type P-type thermoelectric leg 130 or the bulk type N-type thermoelectric leg 140 may be obtained through a process of producing an ingot by heat-treating a thermoelectric material, pulverizing and sieving the ingot to obtain powder for thermoelectric legs, sintering the powder, and cutting the sintered object. In this case, the P-type thermoelectric leg 130 and the N-type thermoelectric leg 140 may be polycrystalline thermoelectric legs. For polycrystalline thermoelectric legs, when the powder for thermoelectric legs is sintered, the powder may be compressed at a pressure of 100 MPa to 200 MPa. For example, when the P-type thermoelectric leg 130 is sintered, the powder for thermoelectric leg may be sintered at a pressure of 100 to 150 MPa, preferably 110 to 140 MPa, and more preferably, 120 to 130 MPa. Further, when the N-type thermoelectric leg 130 is sintered, the powder for thermoelectric leg may be sintered at a pressure of 150 to 200 MPa, preferably 160 to 195 MPa, and more preferably, 170 to 190 MPa. Like the above, when the P-type thermoelectric leg 130 and the N-type thermoelectric leg 140 are polycrystalline thermoelectric legs, the strength of each of the P-type thermoelectric leg 130 and the N-type thermoelectric leg 140 may be increased. The stacked type P-type thermoelectric leg 130 or the stacked type N-type thermoelectric leg 140 may be obtained through a process of forming a unit member by applying a paste including a thermoelectric material onto a sheet-shaped base material, and stacking and then cutting the unit member.

In this case, one pair of the P-type thermoelectric leg 130 and the N-type thermoelectric leg 140 may have the same shape and volume, or may have different shapes and volumes. For example, since electrical conduction characteristics of the P-type thermoelectric leg 130 and the N-type thermoelectric leg 140 are different, a height or cross-sectional area of the N-type thermoelectric leg 140 may be formed differently from a height or cross-sectional area of the P-type thermoelectric leg 130.

In this case, the P-type thermoelectric leg 130 or the N-type thermoelectric leg 140 may have a cylindrical shape, a polygonal pillar shape, an elliptical pillar shape, and the like.

Alternatively, the P-type thermoelectric leg 130 or the N-type thermoelectric leg 140 may have a stacked structure. For example, the P-type thermoelectric legs or the N-type thermoelectric legs may be formed by a method of stacking a plurality of structures coated with a semiconductor material on a sheet-shaped base material, and then cutting the structures. Accordingly, raw material loss may be prevented and the electrical conduction characteristics may be enhanced. Each structure may further include a conductive layer having an opening pattern, and accordingly, an adhesion force between the structures may be increased, thermal conductivity may be lowered, and electrical conductivity may be increased.

Alternatively, the P-type thermoelectric leg 130 or the N-type thermoelectric leg 140 may be formed to have different cross-sectional areas in one thermoelectric leg. For example, cross-sectional areas of both ends disposed to face electrodes in one thermoelectric leg may be formed larger than a cross-sectional area between both ends. Accordingly, since a temperature difference between both ends may be formed to be large, thermoelectric efficiency may be increased.

The performance of the thermoelectric element according to one embodiment of the present disclosure may be expressed as a thermoelectric performance index (figure of merit, ZT). The thermoelectric performance index (ZT) may be expressed as in Equation 1.

ZT=α²·σ·T/k (1)

Here, a is the Seebeck coefficient [V/K], σ is electrical conductivity [S/m], and α2σ is a power factor (W/mK2]). Further, T is a temperature, and k is thermal conductivity [W/mK]. k may be expressed as a⋅cp⋅ρ, wherein a is thermal diffusivity [cm2/S], cp is specific heat [J/gK], and ρ is density [g/cm3].

In order to obtain the thermoelectric performance index of the thermoelectric element, a Z value (V/K) is measured using a Z meter, and the thermoelectric performance index (ZT) may be calculated using the measured Z value.

Here, the lower electrodes 120 disposed between the lower substrate 110 and the P-type thermoelectric leg 130 and the N-type thermoelectric leg 140, and the upper electrode 150 disposed between the upper substrate 160 and the P-type thermoelectric leg 130 and the N-type thermoelectric leg 140 may each include at least one of copper (Cu), silver (Ag), aluminum (Al), and nickel (Ni).

Further, the lower substrate 110 and the upper substrate 160 facing each other may be metal substrates, and thicknesses thereof may be 0.1 mm to 1.5 mm. When the thickness of the metal substrate is less than 0.1 mm or exceeds 1.5 mm, the heat dissipation characteristic or thermal conductivity may be excessively high, and thus reliability of the thermoelectric element may be deteriorated. Further, when the lower substrate 110 and the upper substrate 160 are the metal substrates, insulating layers 170 may be further formed between the lower substrate 110 and the lower electrodes 120 and between the upper substrate 160 and the upper electrode 150, respectively. The insulating layers 170 may include a material having a thermal conductivity of 1 to 20 W/mK, and each insulating layer may include one or more layers.

In this case, the lower substrate 110 and the upper substrate 160 may be formed to have different sizes. For example, a volume, a thickness, or an area of one of the lower substrate 110 and the upper substrate 160 may be formed larger than a volume, a thickness, or an area of the other. Accordingly, it is possible to increase the heat absorption performance or the heat dissipation performance of the thermoelectric element. Preferably, the volume, the thickness, or the area of the lower substrate 110 may be formed larger than the volume, the thickness, or the area of the upper substrate 160. In this case, when the lower substrate 110 is disposed in a high temperature region for the Seebeck effect, when applied as a heating region for the Peltier effect, or when a sealing member for protection from the external environment of a thermoelectric module which will be described later is disposed on the lower substrate 110, the lower substrate 110 may have at least one of the volume, thickness, and area larger than that of the upper substrate 160. In this case, an area of the lower substrate 110 may be formed in a range of 1.2 to 5 times an area of the upper substrate 160. When the area of the lower substrate 110 is less than 1.2 times that of the upper substrate 160, an effect of enhancing heat transfer efficiency is not high, and when the area of the lower substrate 110 exceeds 5 times that of the upper substrate 160, heat transfer efficiency is significantly lowered, and it may be difficult to maintain a basic shape of a thermoelectric module.

Further, a heat dissipation pattern, for example, an uneven pattern may be formed on a surface of at least one of the lower substrate 110 and the upper substrate 160. Accordingly, the heat dissipation performance of the thermoelectric element may be increased. When the uneven pattern is formed on the surface which comes into contact with the P-type thermoelectric leg 130 or the N-type thermoelectric leg 140, the bonding characteristic between the thermoelectric leg and the substrate may also be enhanced. The thermoelectric element 100 includes the lower substrate 110, the lower electrodes 120, the P-type thermoelectric leg 130, the N-type thermoelectric leg 140, the upper electrode 150, and the upper substrate 160.

As shown in FIGS. 4 and 5, sealing members 190 may be further disposed between the lower substrate 110 and the upper substrate 160. The sealing members may be disposed on side surfaces of the lower electrodes 120, the P-type thermoelectric leg 130, the N-type thermoelectric leg 140, and the upper electrode 150 between the lower substrate 110 and the upper substrate 160. Accordingly, the lower electrodes 120, the P-type thermoelectric leg 130, the N-type thermoelectric leg 140, and the upper electrode 150 may be sealed from external moisture, heat, contamination, and the like. Here, the sealing member 190 may include a sealing case 192 disposed to be spaced a predetermined distance apart from side surfaces of the outermost portion of the plurality of lower electrodes 120, the outermost portion of the plurality of P-type thermoelectric legs 130 and the plurality of N-type thermoelectric legs 140, and the outermost portion of the plurality of upper electrodes 150, a sealing material 194 disposed between the sealing case 192 and the lower substrate 110, and a sealing material 196 disposed between the sealing case 192 and the upper substrate 160. Like the above, the sealing case 192 may come into contact with the lower substrate 110 and the upper substrate 160 through the sealing materials 194 and 196. Accordingly, when the sealing case 192 comes into direct contact with the lower substrate 110 and the upper substrate 160, heat conduction occurs through the sealing case 192, and accordingly, a problem in that the temperature difference between the lower substrate 110 and the upper substrate 160 is lowered may be prevented. Here, the sealing materials 194 and 196 may include at least one of an epoxy resin and a silicone resin, or a tape of which both surfaces are coated with at least one of the epoxy resin and the silicone resin. The sealing materials 194 and 194 may serve to airtightly seal between the sealing case 192 and the lower substrate 110 and between the sealing case 192 and the upper substrate 160, and may increase a sealing effect of the lower electrodes 120 and the P-type thermoelectric leg 130, the N-type thermoelectric leg 140 and the upper electrode 150, and may be interchanged with a finishing material, a finishing layer, a waterproofing material, a waterproofing layer, and the like. Here, the sealing material 194 which seals between the sealing case 192 and the lower substrate 110 may be disposed on an upper surface of the lower substrate 110, and the sealing material 196 which seals between the sealing case 192 and the upper substrate 160 may be disposed on a side surface of the upper substrate 160. To this end, the area of the lower substrate 110 may be larger than the area of the upper substrate 160. Meanwhile, a guide groove G, which withdraws lead lines 180 and 182 connected to the electrodes, may be formed in the sealing case 192. To this end, the sealing case 192 may be an injection-molded product formed of plastic or the like, and may be interchanged with a sealing cover. However, the above description of the sealing member is only an example, and the sealing member may be modified into various forms. Although not shown, a heat insulating material may be further included to surround the sealing member. Alternatively, the sealing member may include a heat insulating component.

In the above, the terms “lower substrate 110, lower electrodes 120, upper electrode 150, and upper substrate 160” are used, but are only arbitrarily referred to as upper and lower portions for ease of understanding and convenience of description, and positions may be reversed so that the lower substrate 110 and the lower electrodes 120 may be disposed at an upper side, and the upper electrode 150 and the upper substrate 160 may be disposed at a lower side.

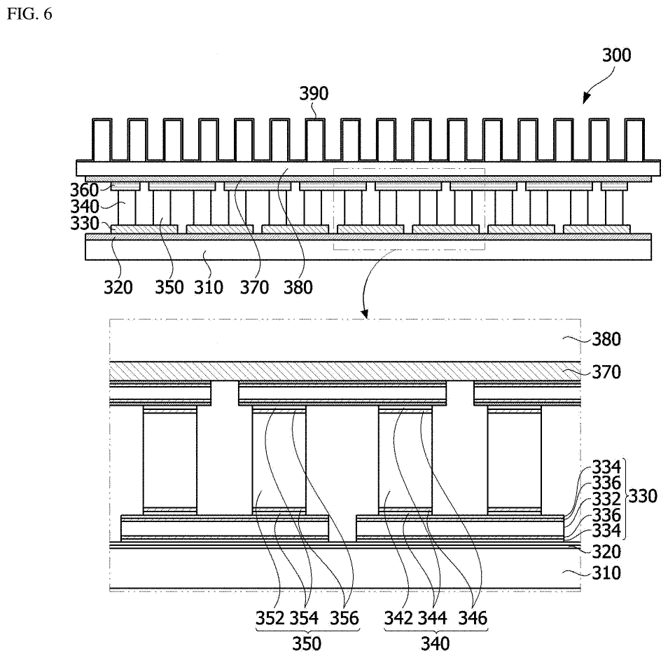

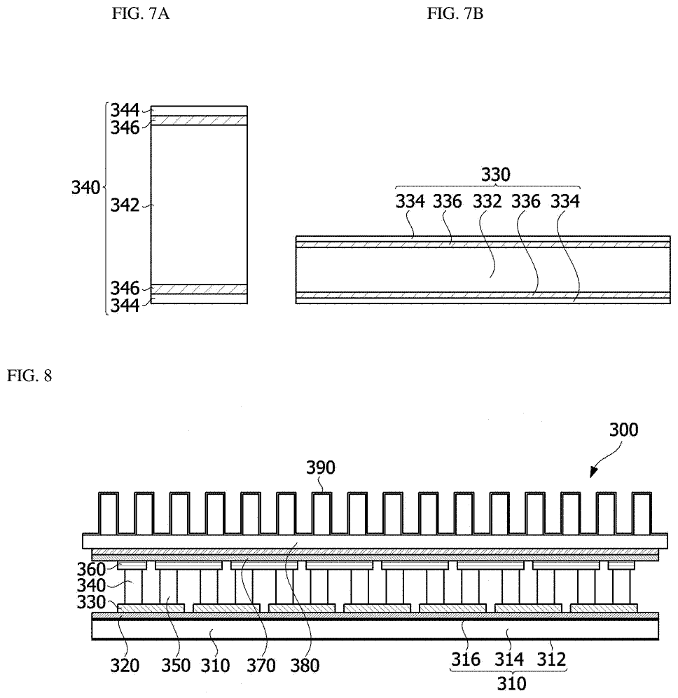

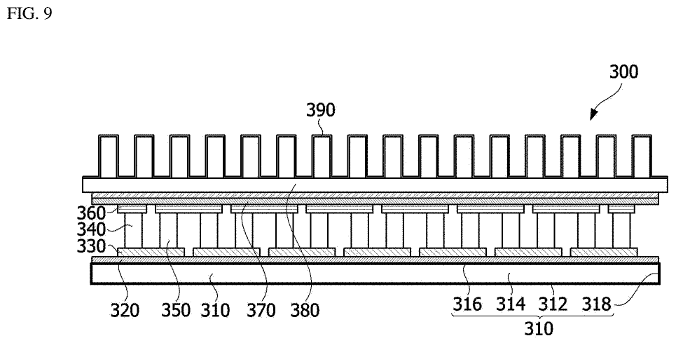

FIG. 6 is a cross-sectional view of a thermoelectric element according to one embodiment of the present disclosure, FIG. 7A is a cross-sectional view of a thermoelectric leg included in the thermoelectric element according to one embodiment of the present disclosure, and FIG. 7B is a cross-sectional view of an electrode included in the thermoelectric element according to one embodiment of the present disclosure. FIG. 8 is a cross-sectional view of a thermoelectric element according to another embodiment of the present disclosure, and FIG. 9 is a cross-sectional view of a thermoelectric element according to still another embodiment of the present disclosure. Overlapping descriptions of contents the same as the contents described in FIGS. 2 to 5 will be omitted.

Referring to FIGS. 6 and 7, a thermoelectric element 300 according to the embodiment of the present disclosure includes a first substrate 310, a first resin layer 320 disposed on the first substrate 310, a plurality of first electrodes 330 disposed on the first resin layer 320, a plurality of P-type thermoelectric legs 340 and a plurality of N-type thermoelectric legs 350 disposed on the plurality of first electrodes 330, a plurality of second electrodes 360 disposed on the plurality of P-type thermoelectric leg 340 and the plurality of N-type thermoelectric leg 350, a second resin layer 370 disposed on the plurality of second electrodes 360, and a second substrate 380 disposed on the second resin layer 370.

As shown in the drawings, a heat sink 390 may be further disposed on the second substrate 380. Although not shown, a sealing member may be further disposed between the first substrate 310 and the second substrate 380.

Generally, since power is connected to the electrode disposed on a low-temperature part side of the thermoelectric element 300, higher withstand voltage performance may be required at the low-temperature part side than a high-temperature part side.

On the other hand, when the thermoelectric element 300 is driven, the high-temperature part side of the thermoelectric element 300 may be exposed to a high temperature, for example, about 180° C. or higher, and due to different coefficients of thermal expansion of the electrode, the insulating layer and the substrate, there may be a problem of peeling between the electrode, the insulating layer, and the substrate. Accordingly, the high-temperature part side of the thermoelectric element 300 may require higher thermal conductivity performance than the low-temperature part side. Specifically, when the heat sink is further disposed on the substrate at the high-temperature part side of the thermoelectric element 300, the bonding strength between the substrate and the heat sink may have great influence on the durability and reliability of the thermoelectric element 300.

According to the embodiment of the present disclosure, each of the first resin layer 320 and the second resin layer 370 may be formed of a resin composition including a resin and an inorganic material. Here, the resin may be an epoxy resin or a silicone resin including polydimethylsiloxane (PDMS). Further, the inorganic material may include at least one of an oxide, carbide, and nitride of at least one of aluminum, titanium, zirconium, boron, and zinc. Accordingly, the first resin layer 320 may enhance an insulating property, a bonding force, and the thermal conductivity performance between the first substrate 310 and the plurality of first electrodes 330, and the second resin layer 370 may enhance an insulating property, a bonding force, and the thermal conductivity performance between the second substrate 380 and the plurality of second electrodes 360. Accordingly, the first resin layer 320 and the second resin layer 370 may have a configuration corresponding to the insulating layer 170 in FIG. 2 or may be a configuration included in the insulating layer 170 in FIG. 2.

In this case, each of the first resin layer 320 and the second resin layer 370 may have a thickness of 10 to 50 μm, preferably, 20 to 45 μm, and more preferably, 30 to 40 μm. In this case, it is advantageous in terms of thermal conductivity performance when each of the first resin layer 320 and the second resin layer 370 is disposed as thin as possible while maintaining insulating performance and adhesion performance. When the first substrate 310 is a low-temperature part, and the second substrate 380 is a high-temperature part, the second resin layer 370 may be required to have higher thermal conductivity performance than the first resin layer 320, and the first resin layer 320 may be required to have higher withstand voltage performance than the second resin layer 370. Accordingly, at least one of the thicknesses and compositions of the first resin layer 320 and the second resin layer 370 may be different. For example, as shown in FIGS. 8 and 9, the second resin layer 370 may include a plurality of layers. For example, the second resin layer 370 may include an adhesive layer and an insulating layer disposed on the adhesive layer, and the adhesive layer may have a composition capable of withstanding a high temperature. For example, the insulating layer may be disposed between the adhesive layer and the second substrate 380, and a part of a side surface of the second electrode 360 may be buried in the adhesive layer. Accordingly, since a contact area between the adhesive layer and the second electrode 360 increases, bonding strength and thermal conductivity between the second electrode 360 and the adhesive layer may increase. To this end, the insulating layer may include a composite including silicon and aluminum and an inorganic filler. Here, the composite may be an organic-inorganic composite composed of an inorganic material including Si and Al elements and an alkyl chain, and may be at least one of an oxide, carbide, and nitride including silicon and aluminum. For example, the composite may include at least one of an Al—Si bond, an Al—O—Si bond, a Si—O bond, an Al—Si—O bond, and an Al—O bond. Like the above, the composite including at least one of an Al—Si bond, an Al—O—Si bond, a Si—O bond, an Al—Si—O bond, and an Al—O bond may have excellent insulating performance, and thus may obtain high withstand voltage performance. Alternatively, the composite may be an oxide, carbide, or nitride further including titanium, zirconium, boron, zinc, and the like in addition to the silicon and the aluminum. To this end, the composite may be obtained through a heat treatment process after mixing aluminum with at least one of an inorganic binder and an organic/inorganic mixed binder. The inorganic binder may include, for example, at least one of silica (SiO2), a metal alkoxide, boron oxide (B2O3), and zinc oxide (ZnO2). The inorganic binder is an inorganic particle, but may become a sol or gel to act as a binder when coming into contact with water. In this case, at least one of silica (SiO2), a metal alkoxide, and boron oxide (B₂O3) may serve to increase adhesion between aluminum or with the metal substrate, and the zinc oxide (ZnO2) may serve to increase the strength of the insulating layer and increase thermal conductivity. The inorganic filler may be dispersed in the composite, and may include at least one of aluminum oxide and a nitride. Here, the nitride may include at least one of boron nitride and aluminum nitride.

Meanwhile, the adhesive layer may be made of a resin layer including at least one of an epoxy resin composition including an epoxy resin and an inorganic filler, and a silicone resin composition including polydimethylsiloxane (PDMS). Accordingly, the adhesive layer may enhance an insulating property, a bonding force, and thermal conductivity performance between the insulating layer and the second electrode 360.

Accordingly, compositions of the insulating layer and the adhesive layer are different from each other, and thus, at least one of the hardness, elastic modulus, tensile strength, elongation, and Young's modulus of the insulating layer and the adhesive layer may be different. Thus, it is possible to control withstand voltage performance, thermal conductivity performance, bonding performance, and thermal shock mitigation performance.

For example, as described above, when the thermoelectric element 300 is driven, a temperature at the high-temperature part side may increase by approximately 180° C. or more, and when the second resin layer 370 is formed of a resin layer having ductility, the second resin layer 370 may serve to mitigate a thermal shock between second electrode 360 and the second substrate 380.

A structure of the second resin layer 370 has been mainly described for convenience of description, but the present disclosure is not limited thereto, and the first resin layer 320 may also have the same structure as the second resin layer 370.

Meanwhile, according to the embodiment of the present disclosure, at least one of the first electrode 330 and the second electrode 360 may include copper layers 332 and 362, first plated layers 334 and 364 respectively disposed on both surfaces of the copper layers 332 and 362, and second plated layers 336 and 366 disposed between both surfaces of the copper layers 332 and 362 and the first plated layers 334 and 364. Further, according to the embodiment of the present disclosure, each of the P-type thermoelectric leg 340 and the N-type thermoelectric leg 350 may include thermoelectric material layers 342 and 352 including BiTe, and bonding layers 344 and 354 respectively disposed on both surfaces of the thermoelectric material layers 342 and 352, and diffusion prevention layers 346 and 356 disposed between the thermoelectric material layers 342 and 352 and the bonding layers 344 and 354. Here, the diffusion prevention layers 346 and 356 prevent the diffusion of Bi or Te, which is a semiconductor raw material in the thermoelectric material layers 342 and 352, to the electrodes, and thus may prevent performance degradation of the thermoelectric element. The diffusion prevention layers 346 and 356 may include, for example, nickel (Ni). Further, the bonding layers 344 and 354 may be bonded to the first electrode 320 and the second electrode 360 by a solder. To this end, the bonding layers 344 and 354 and the solder may include tin (Sn). In this case, thicknesses of the thermoelectric material layers 342 and 352 may be 0.5 to 3 mm, preferably, 1 to 2.5 mm, and more preferably, 1.5 to 2 mm, thicknesses of the bonding layers 344 and 354 may be 1 to 10 μm, preferably, 1 to 7 μm, and more preferably, 3 to 5 μm, and thicknesses of the diffusion prevention layers 346 and 356 may be 1 to 10 μm, preferably, 1 to 7 μm, and more preferably, 3 to 5 μm.

Hereinafter, the first electrode 330 is described as an example for convenience of description, but the same contents may be applied to the second electrode 360 as well.

In this case, the second plated layers 336 serve to prevent the diffusion of copper ions in the copper layer 332, and to this end, the second plated layers 336 may include nickel (Ni).

Further, the first plated layers 334 are formed of a material different from the second plated layers 336, and the first plated layers 334 may be bonded to the first resin layer 320. To this end, the melting point of the first plated layers 334 may be 300° C. or higher, preferably, 600° C. or higher, and more preferably, 900° C. or higher, and electrical conductivity may be 9×106 S/m or higher, preferably, 1×107S/m or higher, and more preferably, 3×107 S/m or higher. For example, the first plated layers 334 may include silver (Ag).

In this case, a thickness of the copper layer 332 may be 0.1 to 0.5 mm, preferably, 0.2 to 0.4 mm, and more preferably, 0.25 to 0.35 mm, and a thickness of the first plated layer 334 may be 0.1 to 10 μm, preferably, 1 to 7 μm, and more preferably, 3 to 5 μm, and a thickness of the second plated layer 336 may be 0.1 to 10 μm, preferably, 1 to 7 μm, and more preferably, 3 to 5 μm. Accordingly, since the first electrode 330 has excellent electrical conduction performance, the first electrode 330 may efficiently perform a function as an electrode.

Further, since the first plated layers 334 have excellent bonding strength with the first resin layer 320 and the solder, a thermoelectric element having high bonding performance may be obtained. In addition, due to high electrical conductivity of the first plated layers 334, a thermoelectric element having excellent thermoelectric performance may be obtained.

In addition, when the first substrate 310, the first resin layer 320, and the plurality of first electrodes 330 are sequentially disposed and then undergo a reflow process to solder the thermoelectric legs 340 and 350, since the problem of a part of the first plated layer 334 of the electrode 330 melting with solder may be prevented, the entire surface of the first plated layer 334 of the first electrode 330 may closely bonded to the first resin layer 320, and accordingly, a thermoelectric element having excellent thermal conductivity performance may be obtained.

Meanwhile, as described above, when it is assumed that the first substrate 310 is disposed at a low-temperature part side of the thermoelectric element 300 and the second substrate 380 is disposed at a high-temperature part side of the thermoelectric element 300, since a wire is connected to the first electrode 330, higher withstand voltage performance may be required at the low-temperature part side than the high-temperature part side, and higher thermal conductivity performance may be required at the high-temperature part side.

Accordingly, according to the embodiment of the present disclosure, the first substrate 310 may be formed of an aluminum substrate, and the second substrate 380 may be formed of a copper substrate. The copper substrate has higher thermal conductivity and electrical conductivity than the aluminum substrate. Accordingly, when the first substrate 310 consists of an aluminum substrate and the second substrate 380 consists of a copper substrate, both the high withstand voltage performance at the low-temperature part side and the high heat dissipation performance at the high-temperature part side may be satisfied.

Meanwhile, according to another embodiment of the present disclosure, as shown in FIG. 8, when the first substrate 310 is an aluminum substrate, the first substrate 310 may be surface-treated. Accordingly, the first substrate 310 may include a first aluminum oxide layer 312, an aluminum layer 314 disposed on the first aluminum oxide layer 312, and a second aluminum oxide layer 316 disposed on the aluminum layer 314. Here, the second aluminum oxide layer 316 may be a configuration corresponding to the insulating layer 170 in FIG. 2 or a configuration included in the insulating layer 170 in FIG. 2. That is, the insulating layer 170 in FIG. 2 may include the second aluminum oxide layer 316 and the first resin layer 320. Like the above, when the aluminum oxide layers are disposed on both surfaces of the first substrate 310, the withstand voltage performance may be increased without increasing a thermal resistance of the first substrate 310, and the surface of the first substrate 310 may be prevented from corroding.

In this case, a thickness of the aluminum layer 314 may be 0.1 to 2 mm, preferably, 0.3 to 1.5 mm, and more preferably, 0.5 to 1.2 mm, a thickness of each of the first aluminum oxide layer 312 and the second aluminum oxide layer 316 may be 10 to 100 μm, preferably, 20 to 80 μm, and more preferably, 30 to 60 μm. When the thickness of each of the first aluminum oxide layer 312 and the second aluminum oxide layer 316 satisfies this numerical range, high thermal conductivity performance and high withstand voltage performance may be simultaneously satisfied.

In this case, the sum of thicknesses of the first aluminum oxide layer 312, the second aluminum oxide layer 316, and the first resin layer 320 may be 80 μm or more, and preferably, 80 to 480 μm. Generally, as the thickness of the insulating layer increases, withstand voltage performance may be increased. However, as the thickness of the insulating layer increases, there is a problem in that thermal resistance also increases. However, in the embodiment of the present disclosure, since the aluminum oxide layers are disposed on both surfaces of the first substrate 310, it is possible to simultaneously satisfy high thermal conductivity performance and high withstand voltage performance.

In this case, at least one of the first aluminum oxide layer 312 and the second aluminum oxide layer 316 may be formed by anodizing the aluminum substrate. Alternatively, at least one of the first aluminum oxide layer 312 and the second aluminum oxide layer 316 may be formed by a dipping process or a spray process.

Alternatively, as shown in FIG. 9, at least one of the first aluminum oxide layer 312 and the second aluminum oxide layer 316 may be connected to each other at the side surface of the aluminum layer by forming an extending portion 318 extending along the aluminum layer 314. Accordingly, an aluminum oxide layer may be formed on all surfaces of the first substrate 310, and it is possible to further increase the withstand voltage performance at the low-temperature part side.

Meanwhile, as described above, a heat sink may be further disposed at the high-temperature part side. The second substrate 380 and the heat sink 390 at the high-temperature part side may be integrally formed, but a separate second substrate 380 and the heat sink 390 may be bonded to each other. In this case, when a metal oxide layer is formed on the second substrate 380, bonding between the second substrate 380 and the heat sink 390 may be difficult. Accordingly, in order to increase the bonding strength between the second substrate 380 and the heat sink 390, the metal oxide layer may not be formed between the second substrate 380 and the heat sink 390. That is, when the second substrate 380 is a copper substrate, a copper oxide layer may not be formed on a surface of the copper substrate. To this end, the copper substrate may be surface-treated in advance to prevent oxidation of the copper substrate. For example, when a copper substrate is plated with a metal layer such as nickel having a property of not being easily oxidized compared to copper, it is possible to prevent the formation of a metal oxide layer on the copper substrate. When the second substrate 380 is a copper substrate and the surface of the copper substrate is plated with nickel, the heat sink 390 may also be formed of a copper material whose surface is plated with nickel.

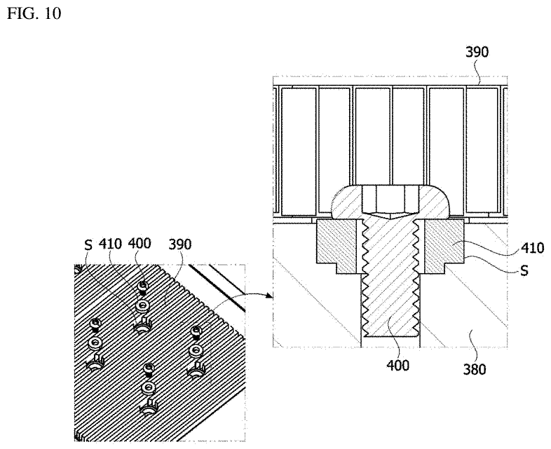

Alternatively, the second substrate 380 and the heat sink 390 may be bonded by a separate fastening member. FIG. 10 exemplifies a bonding structure between the second substrate 380 and the heat sink 390. Referring to FIG. 10, the heat sink 390 and the second substrate 380 may be fastened by a plurality of fastening members 400. To this end, a through hole S through which the fastening members 400 pass may be formed in the heat sink 390 and the second substrate 380. Here, a separate insulator 410 may be further disposed between the through hole S and the fastening member 400. The separate insulator 410 may be an insulator surrounding an outer circumferential surface of the fastening member 400 or an insulator surrounding a wall surface of the through hole S. Accordingly, it is possible to increase an insulating distance of the thermoelectric element.

Like the above, according to the embodiment of the present disclosure, a thermoelectric element of which thermoelectric performance and bonding performance are excellent may be obtained.

Although preferable embodiments of the present disclosure are described above, those skilled in the art may variously modify and change the present disclosure within the scope of the spirit and area of the present disclosure disclosed in the claims which will be described later.

1. A thermoelectric element comprising:
a first substrate;
a first resin layer disposed on the first substrate;
a first electrode disposed on the first resin layer;
a semiconductor structure disposed on the first electrode;
a second electrode disposed on the semiconductor structure;
a second resin layer disposed on the second electrode; and
a second substrate disposed on the second resin layer,
wherein at least one of the first electrode and the second electrode includes a copper layer, first plated layers disposed on both surfaces of the copper layer, and second plated layers disposed between both surfaces of the copper layer and the first plated layers,
materials of the first plated layer and the second plated layer are different from each other, and
each of the first plated layers has a melting point greater than or equal to 300° C., and an electrical conductivity greater than or equal to 9×10⁶ S/m.

2. The thermoelectric element of claim 1, wherein at least one of the first resin layer and the second resin layer is bonded to the first plated layer.

3. The thermoelectric element of claim 2, wherein:
the first substrate is an aluminum substrate;
the second substrate is a copper substrate; and
first aluminum oxide layer is further disposed between the aluminum substrate and the first resin layer.

4. The thermoelectric element of claim 3, wherein a second aluminum oxide layer is further disposed on a surface, among both surfaces of the aluminum substrate, opposite a surface on which the first resin layer is disposed.

5. The thermoelectric element of claim 3, further comprising a heat sink disposed on the second substrate.

6. The thermoelectric element of claim 2, wherein:
the semiconductor structure includes a thermoelectric material layer including BiTe, and bonding layers disposed on both surfaces of the thermoelectric material layer; and
the bonding layers are bonded to the first plated layer by a solder.

7. The thermoelectric element of claim 6, wherein the bonding layer and the solder include tin (Sn).

8. The thermoelectric element of claim 7, further comprising a diffusion prevention layer disposed between the thermoelectric material layer and the bonding layer,
wherein the diffusion prevention layer includes nickel (Ni).

9. The thermoelectric element of claim 1, wherein:
the first plated layer includes silver (Ag); and
the second plated layer includes nickel (Ni).

10. The thermoelectric element of claim 9, wherein a thickness of the first plated layer is 0.1 μm to 10 μm.

11. The thermoelectric element of claim 1, wherein at least one of the first resin layer and the second resin layer includes a plurality of layers.

12. The thermoelectric element of claim 1, wherein at least one of withstand voltage performance and thermal conductivity performance of the first resin layer differs from at least one of withstand voltage performance and thermal conductivity performance of the second resin layer.

13. The thermoelectric element of claim 12, wherein:
the first substrate is an aluminum substrate;
the second substrate is a copper substrate;
the thermal conductivity performance of the second resin layer is higher than the thermal conductivity performance of the first resin layer; and
the withstand voltage performance of the first resin layer is higher than the withstand voltage performance of the second resin layer.

14. The thermoelectric element of claim 1, further comprising a first insulating layer disposed between the first substrate and the first resin layer, wherein a part of a side surface of the first electrode is buried in the first resin layer.

15. The thermoelectric element of claim 1, further comprising a second insulating layer disposed between the second substrate and the second resin layer, wherein a part of a side surface of the second electrode is buried in the second resin layer.

16. The thermoelectric element of claim 4,
wherein the first aluminum oxide layer and the second aluminum oxide layer are connected to each other on a side surface of the aluminum substrate.

17. The thermoelectric element of claim 5,
wherein a surface of the copper substrate and a surface of the heatsink are plated by Ni.

18. A thermoelectric element comprising:
a first substrate,
a first electrode disposed on the first resin layer,
a P-type thermoelectric leg and an N-type thermoelectric leg disposed on the first electrode,
a second electrode disposed on the P-type thermoelectric leg and the N-type thermoelectric leg,
a second resin layer disposed on the second electrode, and
a second substrate disposed on the second resin layer,
wherein at least one of the first electrode and the second electrode includes a copper (Cu) layer, and plated layers disposed on both surfaces of the copper layer, and
wherein the plated layers include silver (Ag), and the plated layers is bonded to at least one of the first resin layer and the second resin layer.

19. The thermoelectric element of claim 18, wherein each of the P-type thermoelectric leg and the N-type thermoelectric leg includes a thermoelectric material layer including BiTe, and bonding layers disposed on both surfaces of the thermoelectric material layer, and the bonding layers is bonded to the plated layer by a solder.

20. The thermoelectric element of claim 19, wherein the bonding layer and the solder include tin (Sn).
